(19) United States
(12) Patent Application Publication
(10) Pub. No.: US 2025/0284859 A1
(43) Pub. Date: Sep. 11, 2025

(54) SYSTEMS AND METHODS FOR PREDICTING A TIME TILL FAILURE OF A LAMP

(71) Applicant: ABB Schweiz AG, Baden (CH)

(72) Inventors: Yvan Mimeault, Quebec (CA); Tommy Dallaire, Quebec (CA)

(21) Appl. No.: 18/597,544

(22) Filed: Mar. 6, 2024

(51) Int. Cl. G06F 30/20

(52) U.S. Cl. CPC G06F 30/20

(57) ABSTRACT

A system for operating a halogen lamp including a sensor configured to detect a parameter of the lamp and a processor for receiving the parameter detected by the sensor over a data collection period of time and generating a model based on, at least in part, the received parameter detected by the sensor. The processor uses the model to predict a time till at least a pre-failure event when a pre-failure criterion will be satisfied.

### BACKGROUND

The field of the disclosure relates generally to systems and methods of predicting failure of an electronic device, and more particularly, to systems and methods for advanced prediction of a time till failure of a lamp.

Lamps, particularly Halogen lamps, may be used in various research or technical applications by supplying light to instruments such as spectrometers, which have been used in detecting chemical compositions of a sample in a broad range of applications, such as semiconductor microchip fabrication and detection of contaminants in fuel gas production. For example, Halogen lamps are used in spectrometer applications, as they emit light that may be in a broad spectral distribution spanning the range of infrared, visible, and/or ultraviolet light. Additionally, analytical instrumentation, including halogen lamps, may be used for applications requiring real time monitoring of continuous processes. These continuous processes require a high reliability and continuous operation of the analytical instrumentation. Accordingly, advanced prediction of failure of instrumentation is desired to enable users to take preventative measures or schedule downtimes for maintenance procedures. Halogen lamps failure mechanisms, including filament breakage, occurs suddenly and without warning. There are no known systems which provide advanced prediction of a time till failure of an electronic device, such as a halogen lamp.

Known assemblies and methods are disadvantaged in some aspects in providing advanced prediction of a time till failure of electronic devices.

### BRIEF DESCRIPTION

In one aspect, a system for operating a halogen lamp is provided. The system includes a sensor configured to detect a parameter of the lamp and a processor communicatively coupled to at least one memory storing instructions that when executed by the processor cause the processor to receive the parameter detected by the sensor over a data collection period of time and generate a model based on, at least in part, the received parameter detected by the sensor over the data collection period of time. The instructions that when executed by the processor cause the processor to, using the model, predict a time till at least a pre-failure event when a pre-failure criterion will be satisfied.

In another aspect, a method for predicting a time till failure of a lamp is provided. The method includes receiving a parameter detected by a sensor over a data collection period of time and generating a model based on, at least in part, the received parameter detected by the sensor over the data collection period of time. The method includes, using the model, predict a time till at least a pre-failure event when a pre-failure criterion will be satisfied.

In one more aspect, a non-transitory computer readable medium having computer-executable instructions embodied thereon for implementing operating a halogen lamp is provided. When executed by at least one processor, the computer-executable instructions cause the at least one processor to receive a parameter detected by a sensor over a data collection period of time and generate a model based on, at least in part, the received parameter detected by the sensor over the data collection period of time. The computer-executable instructions cause the at least one processor to, using the model, predict a time till at least a pre-failure event when a pre-failure criterion will be satisfied.

### BRIEF DESCRIPTION OF DRAWINGS

These and other features, aspects, and advantages of the present disclosure will become better understood when the following detailed description is read with reference to the accompanying drawings in which like characters represent like parts throughout the drawings.

FIG. 1A is a perspective view of an example halogen lamp assembly.

FIG. 1B is a perspective view of an example filament assembly for use with the known halogen lamp assembly shown in FIG. 1A.

FIG. 2A is a perspective view of an example failed coil of a filament assembly for the halogen lamp assembly shown in FIG. 1A-B.

FIG. 2B is a perspective view of an example failed lead of a filament assembly for the halogen lamp assembly shown in FIG. 1A-B.

FIG. 3 is an example graph of current vs. lifespan for an example electronic device.

FIG. 4 is a graph of an example mortality curve for halogen lamp lifespans.

FIG. 5 is a graph of an example life and luminous output vs. percent of the design voltage for halogen lamps.

FIG. 6 is a schematic diagram of an exemplary electronic lifespan prediction system.

FIG. 7 is an example graph of current vs. lifespan for an example electronic device showing different phases, including an initiation phase, a primary phase, a pre-failure phase, and a final phase, and lifespan events.

FIG. 8 is another example graph of current vs. lifespan for a plurality of different example electronic devices showing the initiation phase.

FIG. 9 is another example graph of current vs. lifespan for a plurality of different example electronic devices showing the initiation phase and the primary phase.

FIG. 10 is another example graph of current vs. lifespan for a plurality of different example electronic devices showing the primary phase for both a data collection curve and a model prediction curve.

FIG. 11 is another example graph of current vs. lifespan for a plurality of different example electronic devices showing the initiation phase and the primary phase including a data collection subphase and a model subphase for both the data collection and the model prediction curves.

FIG. 12 is another example graph of current vs. lifespan for an example electronic device showing the pre-failure phase.

FIG. 13 is another example graph of current vs. lifespan for an example electronic device showing the final phase.

FIG. 14 is another example graph of current vs. lifespan for a plurality of electronic devices showing the phases and lifespan events for both the data collection and the model prediction curves.

FIG. 15 is another example graph of current vs. lifespan for a plurality of electronic devices showing phases and lifespan events for both the data collection and the model prediction curves.

FIG. 16 is a method flow diagram for operating an electronic device for use with the exemplary electronic lifespan prediction system shown in FIG. 6

FIG. 17 is another method flow diagram for operating an electronic device for use with the exemplary electronic device lifespan prediction system shown in FIG. 6.

FIG. 18 is a block diagram of an example user computer device.

FIG. 19 is a block diagram of an example server computer device.

### DETAILED DESCRIPTION

In the following specification and the claims, reference will be made to a number of terms, which shall be defined to have the following meanings.

The singular forms “a,” “an,” and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

As used herein, the terms “processor” and “computer” and related terms, e.g., “processing device,” “computing device,” and “controller” are not limited to just those integrated circuits referred to in the art as a computer, but broadly refers to a microcontroller, a microcomputer, a programmable logic controller (PLC), an application specific integrated circuit (ASIC), and other programmable circuits, and these terms are used interchangeably herein. In the embodiments described herein, memory may include, but is not limited to, a computer-readable medium, such as a random-access memory (RAM), and a computer-readable non-volatile medium, such as flash memory. Alternatively, a compact disc-read only memory (CD-ROM), a magneto-optical disk (MOD), and/or a digital versatile disc (DVD) may also be used. Also, in the embodiments described herein, additional input channels may be, but are not limited to, computer peripherals associated with an operator interface such as a mouse and a keyboard. Alternatively, other computer peripherals may also be used that may include, for example, but not be limited to, a scanner. Furthermore, in the exemplary embodiment, additional output channels may include, but not be limited to, an operator interface monitor.

Further, as used herein, the terms “software” and “firmware” are interchangeable and include any computer program stored in memory for execution by personal computers, workstations, clients, and servers.

As used herein, the term “non-transitory computer-readable media” is intended to be representative of any tangible computer-based device implemented in any method or technology for short-term and long-term storage of information, such as, computer-readable instructions, data structures, program modules and sub-modules, or other data in any device. Therefore, the methods described herein may be encoded as executable instructions embodied in a tangible, non-transitory, computer readable medium, including, without limitation, a storage device and/or a memory device. Such instructions, when executed by a processor, cause the processor to perform at least a portion of the methods described herein. Moreover, as used herein, the term “non-transitory computer-readable media” includes all tangible, computer-readable media, including, without limitation, non-transitory computer storage devices, including, without limitation, volatile and nonvolatile media, and removable and non-removable media such as a firmware, physical and virtual storage, CD-ROMs, DVDs, and any other digital source such as a network or the Internet, as well as yet to be developed digital means, with the sole exception being a transitory, propagating signal.

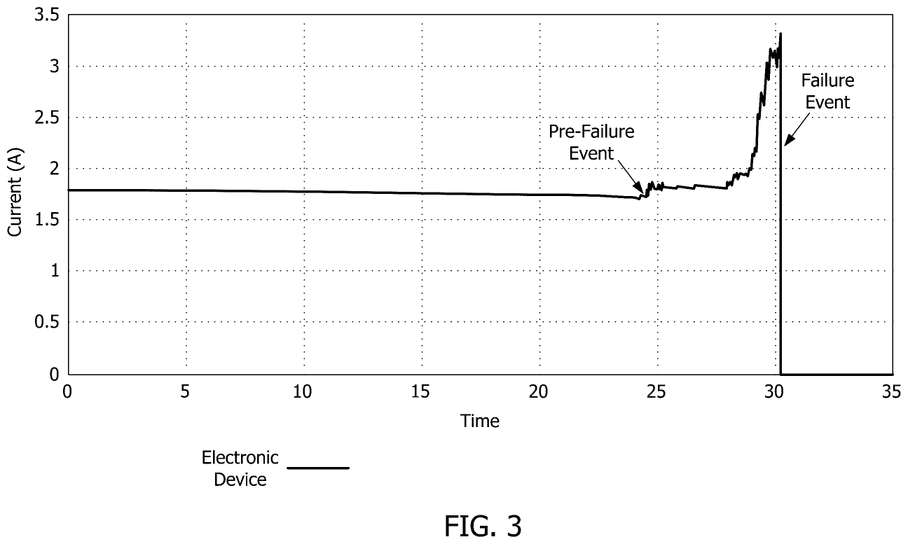

Methods of detecting lamp failure merely monitor fluctuations in the voltage and/or current to detect the presence of a short circuit, e.g., portions of the coil portion of the filament have fused together, giving very short notice of a subsequent lamp failure. For example, some methods merely compare measured voltage to saved reference values to detect the occurrence of the start of failure of the lamp while providing no predictions nor any advanced warning of a failure. In some examples, merely comparing measured voltage to saved reference values to detect the occurrence of the start of failure of the lamp may be insufficient to predict failure with any advanced warning, see FIG. 3, for example, showing current of an example lamp over the lifespan of the lamp, wherein the current appears to have relatively minimal current spikes prior to failure, e.g., prior to pre-failure. For example, prior to the pre-failure event, there are no detectable or obvious signs that the pre-failure event will occur. As such, these some methods cannot predict failure with sufficient warning to enable users to prepare to replace a lamp. Furthermore, these methods do not utilize any intervention methods to delay or compensate for a detected lamp failure.

Exemplary embodiments of systems and methods of advanced prediction of a time till failure of an electronic device are described herein. In the exemplary embodiments described herein, the advanced prediction and warning of a time till failure of an electronic device enables users to prepare for, or schedule, replacement, or repair of the electronic device. In the exemplary embodiments described herein, the electronic device is embodied as a halogen lamp, e.g., for use with real-time monitoring applications of a continuous process, as examples for illustration purposes only. Systems and methods described herein may be applied to any lamp. Method aspects will be in part apparent and in part explicitly discussed in the following description.

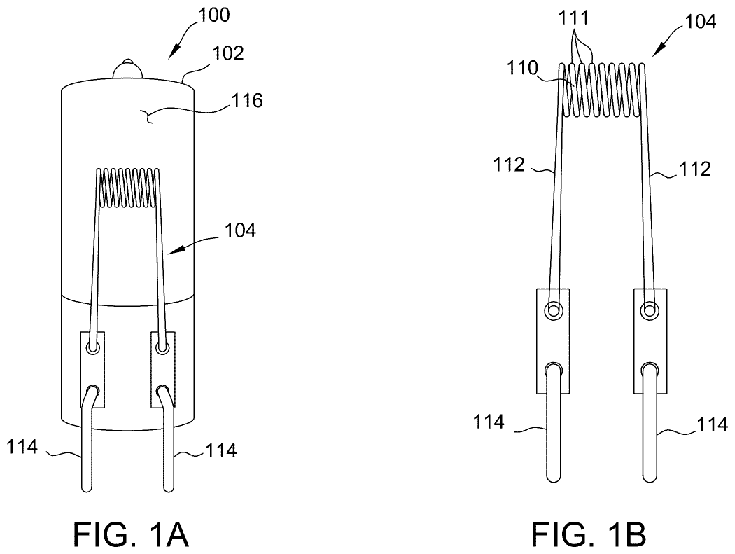

FIG. 1A is a front view of an example halogen lamp assembly 100. The assembly 100 includes an exhaust tube 102 and a filament assembly 104 at least partially contained within the exhaust tube 102. FIG. 1B is a front view of the filament assembly 104, removed from the exhaust tube 102. The filament assembly 104 includes a coil 110 including a plurality of turns 111, and a pair of leads 112 extending from each end of the coil 110. The coil 110 and at least a portion of the leads 112 are contained within the exhaust tube 102 and at least a portion of the leads 112 are disposed outside of the exhaust tube 102. The leads 112 may be connected to a pair of pins 114 for connecting the filament assembly 104 to a circuit, e.g., such that a voltage and/or a current may be supplied to the filament assembly 104. In some embodiments, the exhaust tube 102 is composed of fused silica quartz glass and the filament assembly 104 is composed of tungsten. The exhaust tube 102 includes a sealed cavity 116 containing halogen and/or additional or alternative suitable gases. In other embodiments, the halogen lamp assembly 100 may be composed of alternative materials and/or the cavity 116 maybe filled with other suitable gases. The systems and methods described herein for advanced prediction of time till failure of an electronic device, may be utilized with any other suitable types of lamps, or additional or alternative electronic devices, described below.

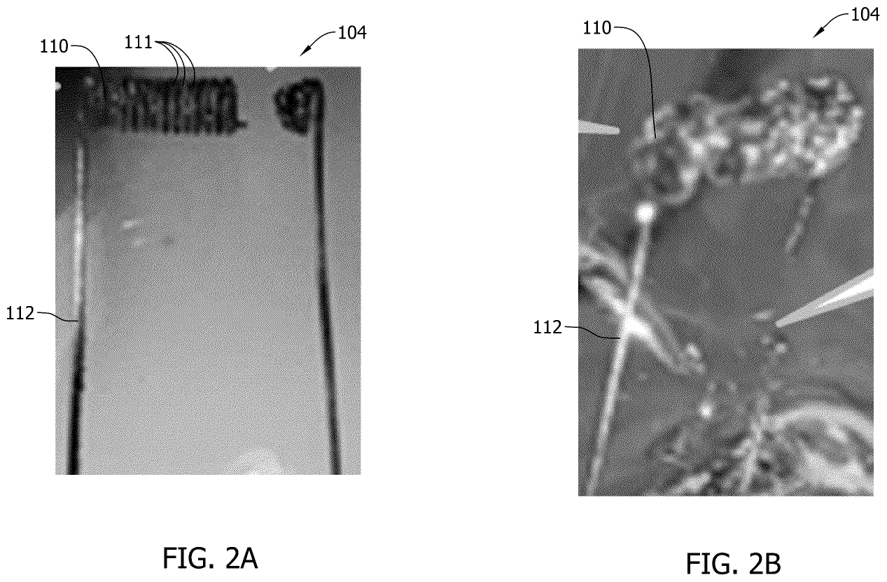

Lamps, e.g., the halogen lamp assembly 100, have various failure mechanisms, such as filament assembly breakage (e.g., coil 110 or leads 112), shown in FIGS. 2A and 2B which occurs when the tungsten filament evaporates over time. In some failures, one or more adjacent turns 111 may fuse together or are in contact decreasing the resistance of the coil proportionally relative to the number of turns relative to the overall length of the coil. The fusing of adjacent turns and decrease in resistance causes fluctuations in the current, e.g., see FIG. 3, showing a fluctuations in current when time is about equal to 25. Although less common as compared to filament breakage, additional and/or alternative failure mechanisms are envisioned, such as filament notching, bulb cracking, and/or filament detachment. Filament notching may occur when the lamp is run at low temperatures and filament detaching may occur when the lamp is exposed to vibration.

In some embodiments, lamps may fail suddenly, due to filament breakage, upon powering up a cold lamp filament. Furthermore, there is limited warning before the halogen lamp will fail, for example, halogen lamps do not blacken and only undergo minor changes in photometric output characteristics as the lamps age. Similar to other incandescent lamps, some halogen lamp lifetimes are determined by the vaporization rate of tungsten from the filament. If the filament does not have a constant temperature along the entire length of the filament but instead has regions of much higher temperature resulting from manufacturing defects, such as uneven filament thickness, or internal structural variations, then the filament will usually fail due to premature breakage. Even though vaporized tungsten is returned to the filament by the halogen regenerative cycle the material is unfortunately deposited on cooler regions of the filament and not those critical hotspots where thinning of the filament typically occurs. Accordingly, conventionally, predicting when any particular filament will fail in lamps that are operated continuously remains a challenge.

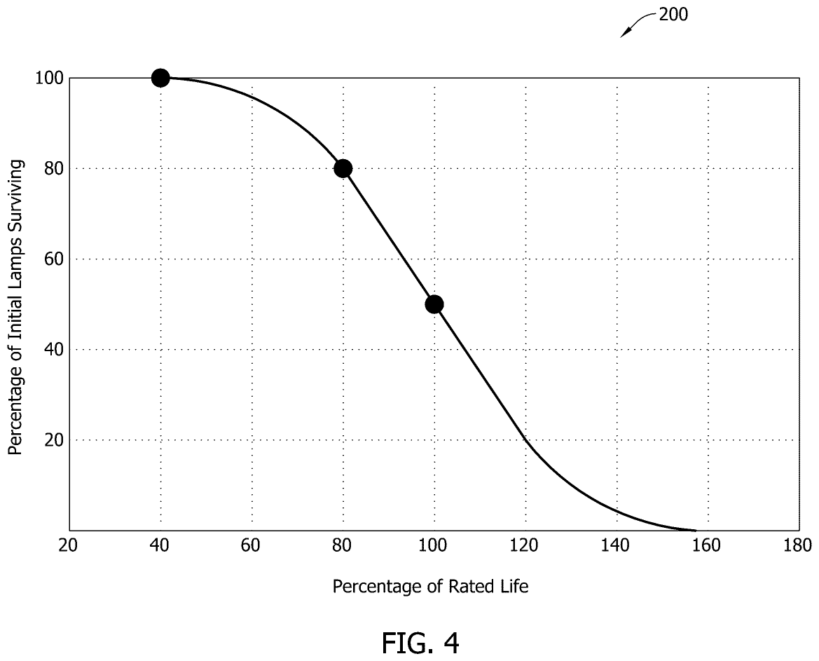

FIG. 4 is a graph of an example mortality curve for halogen lamp assemblies, e.g., such as the halogen lamp assembly 100 shown in FIG. 1A. Estimates for the lifespan of halogen lamps may be determined by a vaporization rate of the filament. Due to slight variations in lamp manufacturing, it is unlikely that each individual lamp will have an actual lifespan that exactly matches the estimated lifespan. Accordingly, lamp lifespans are determined by averaging lifespans for a large group of lamps. As seen in graph 200, there is 100% survival rate after 40% of estimated lifespans, there is 80% survival rate after 80% of estimated lifespans, and there is 50% survival rate after 100% of estimated lifespans. Due to this large distribution of estimated lifespans, this information cannot be used to predict a time of failure or to guarantee a timespan for a specific lamp.

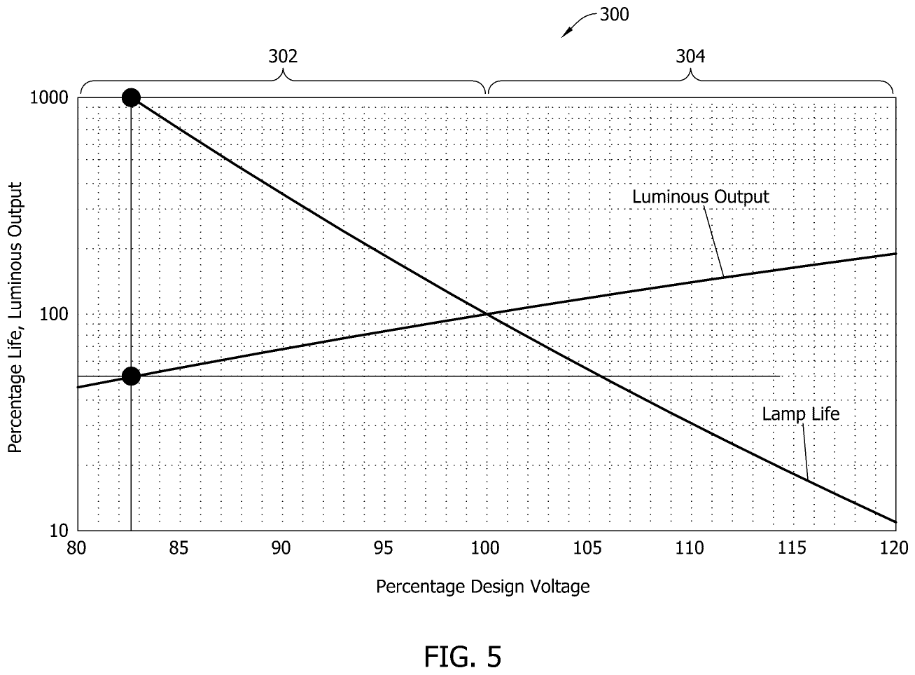

FIG. 5 is a graph of an example life and luminous output vs. percent of the design voltage supplied to an example lamp, e.g., halogen lamp assembly 100 shown in FIG. 1A. The design voltage may be associated with a manufacturing recommendation or an electronic rating for power or voltages that are prescribed to be supplied to the lamp during use. As shown in the graph 300, luminous output and percent life are dependent on the percent design voltage. The graph 300 includes a low voltage region 302 and a high voltage region 304. Generally, running a lamp at a voltage that is lower than the design voltage, e.g., low voltage region 302, decreases the luminous output and increases the percent life, as compared to running the lamp at a voltage that is higher than the design voltage, e.g., high voltage region 304.

In some embodiments described herein, the system and methods may utilize the life and luminous output and percent design (also referred to as nominal) voltage to determine an optimal power level and/or voltage level to be supplied to a lamp to increase the lifespan of the lamp while maintaining a luminous output suitable for the application use of the lamp. In some embodiments described herein, the systems and methods may include selectively adjusting, e.g., reducing, the power, e.g., a current and/or a voltage supplied to the lamp to extend the life of the lamp, based on a predicted time till failure of the lamp. In some embodiments, the systems and methods included herein may use a feedback control loop to maintain or control the supply of power, current, or a voltage, e.g., at a target setpoint. For example, the systems and methods may determine a voltage level that is approximately 82.5% of the nominal value of the voltage to increase the lifespan by a factor of 10 with a lower luminous output. Additionally, and/or alternatively, the reduction in voltage may decrease the current to approximately 92% of the nominal current.

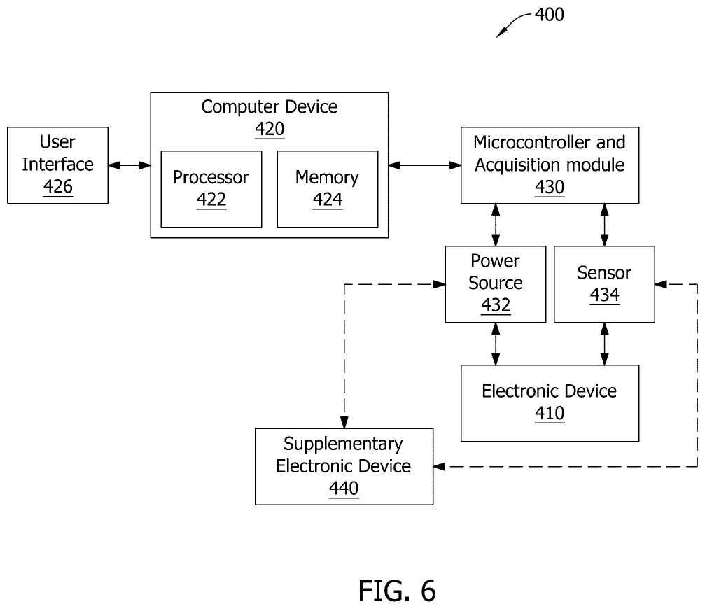

FIG. 6 is a schematic diagram of an exemplary lifespan system 400 for predicting a time till failure and detecting lifespan events of an electronic device 410. In the exemplary embodiment, the electronic device 410 may be embodied as a halogen lamp, e.g., such as the halogen lamp assembly 100 shown and described in relation to FIGS. 1A-1B. In other embodiments, the electronic device 410 may be any suitable lamp including a filament that emits light when power is supplied to the filament. In alternative embodiments, the electronic device 410 may be any suitable device having a component for which a power may be supplied and a parameter may be detected, e.g., a current, voltage, or resistance, for example, and without limitation, a heater, lamps such as incandescent lamps or fluorescent lamps, and diodes, e.g., laser diodes. The lamps may be filled with any suitable gases, such as, mercury vapor, metal halide, high-pressure sodium vapor, low-pressure sodium vapor.

The system 400 may include a computer device 420 including a processor 422 and at least one memory 424. The system 400 includes a user interface 426, associated with, or communicatively coupled to the computer device 420 for presenting information to a user such as the predicted time till failure or detected lifespan events. The user interface 426 may include a display, such as a screen and/or lights, for presenting the information to the user and one or more user inputs (e.g., buttons, keyboard, touchscreen, knobs, etc.) enabling users to interact with the computer device 420 and/or other components of the system 400. In some embodiments, the user interface 426 may include a speaker for emitting noises, for example, to warn users of a predicted time till failure or a detected lifespan event of the electronic device 410.

The system 400 includes a microcontroller and acquisition module 430, that is associated with, or communicatively coupled to, the computer device 420. The microcontroller and acquisition module 430 are communicatively coupled to a power source 432. The module 430 may transmit one or more signals to the power source 432 causing the power source 432 to supply power to the electronic device 410. For example, power source 432 may supply power, e.g., supply a voltage or supply a current, to the electronic device 410.

The microcontroller and acquisition module 430 is also communicatively coupled to a sensor 434 for detecting a parameter of the electronic device 410. The module 430 may receive one or more signals from the sensor 434 as the sensor 434 detects, in real-time, the parameter. In some embodiments, the user interface 426 may be used to present data such as the parameter detected by the sensor 434. The microcontroller and acquisition module 430 and/or the sensor 434 may have any suitable data collection rate, e.g., every second, every ten seconds, every minute, every hour, or every day as necessary for the system 400 to function as described herein. In some embodiments the data collection rate changes over the lifespan of the electronic device. In some embodiments, the lifespan, depending on the specific type of electronic device 410 may be days, months, or even years. In some cases, data collection rates during an early period of time during the lifespan may be lower compared to data collection rates later in the lifespan. In the exemplary embodiment, the sensor 434 includes a current sensor for detecting a current of the electronic device 410, e.g., a current of the filament assembly 104 of the halogen lamp assembly 100. In some embodiments, the sensor 434 includes a voltage sensor for detecting a voltage of the electronic device 410, e.g., a voltage across the filament assembly 104 of the halogen lamp assembly 100. In other embodiments, the sensor 434 includes any additional and/or alternative sensors for detecting any parameter, e.g., temperature, optical power, and/or spectral density, of the electronic device 410.

In some embodiments, the power source 432 may supply a power level to achieve a constant voltage, to the electronic device 410. The resistance of the electronic device 410, e.g., the filament assembly 104, may vary over the lifespan. For example, the resistance may decrease when adjacent turns 111 fuse together. In some embodiments, the sensor 434 is a voltage sensor and the module 430 adjusts the supplied voltage to maintain a constant voltage in the electronic device 410. In some embodiments, the power source 432 may supply a variable power. In embodiments described herein, the value of the power supplied by the power source 432 is selectively adjustable (e.g., via the user interface 426 or programed into the computer device 420 or microcontroller and acquisition module 430). In some embodiments, the microcontroller and acquisition module 430 transmits one or more signals to the power source 432 causing the power source 432 to ramp, e.g., gradually increase, supplied power during an initiation phase, described below, and then subsequent to the initiation phase, the microcontroller and acquisition module 430 transmits one or more signals to the power source 432 causing the power source 432 to supply a constant value of power. In some alternative embodiments, the power source 432 may supply a constant voltage, or alternatively, the power source 432 may supply a constant current, to the electronic device 410.

In some embodiments described herein, a user may select the constant value of power to be supplied to the electronic device 410, e.g., via the user interface 426. In some embodiments described herein, each electronic device 410 may be associated with a design voltage as is specified by a manufacturer, see FIG. 5. In some embodiments the microcontroller and acquisition module 430 is configured to determine, using the design voltage, a suitable constant value of power to be supplied to the electronic device 410 by the power source 432 in order to target and/or increase a lifespan of the electronic device 410. In alternative embodiments, the microcontroller and acquisition module 430 is configured to use the design voltage as the constant value of power supplied to the electronic device 410.

In the embodiments described herein, at least one of the computer device 420 and/or the microcontroller and acquisition module 430 may be enabled to execute one or more method steps for predicting a time till failure or detecting lifespan events, as will be described in further detail herein.

In some embodiments, the system 400 further includes at least one of a supplementary electronic device 440. The supplementary electronic device 440 may be selectively communicatively coupled to the power source 432, the sensor 434, and/or microcontroller and acquisition module 430. In some embodiments, the at least one supplementary electronic device 440 is a backup device to the electronic device 410. For example, when the electronic device 410 has reached failure or is predicted to reach failure imminently, the microcontroller and acquisition module 430 may automatically turn off the electronic device 410, e.g., the module 430 transmits one or more signals to the power source 432 causing the power source 432 to stop supplying power to the electronic device 410. Simultaneously and/or subsequently, the microcontroller and acquisition module 430 automatically turns on the supplementary electronic device 440, e.g., the module 430 transmits one or more signals to the power source 432, causing the power source 432 to supply power to the supplementary electronic device 440. accordingly, in some embodiments, the system 400 is enabled to continuously run at least one electronic device 410 or supplementary electronic device 440 without downtime. For example, in the exemplary embodiment, the system 400 is enabled to continuously emit light by a halogen lamp without downtime.

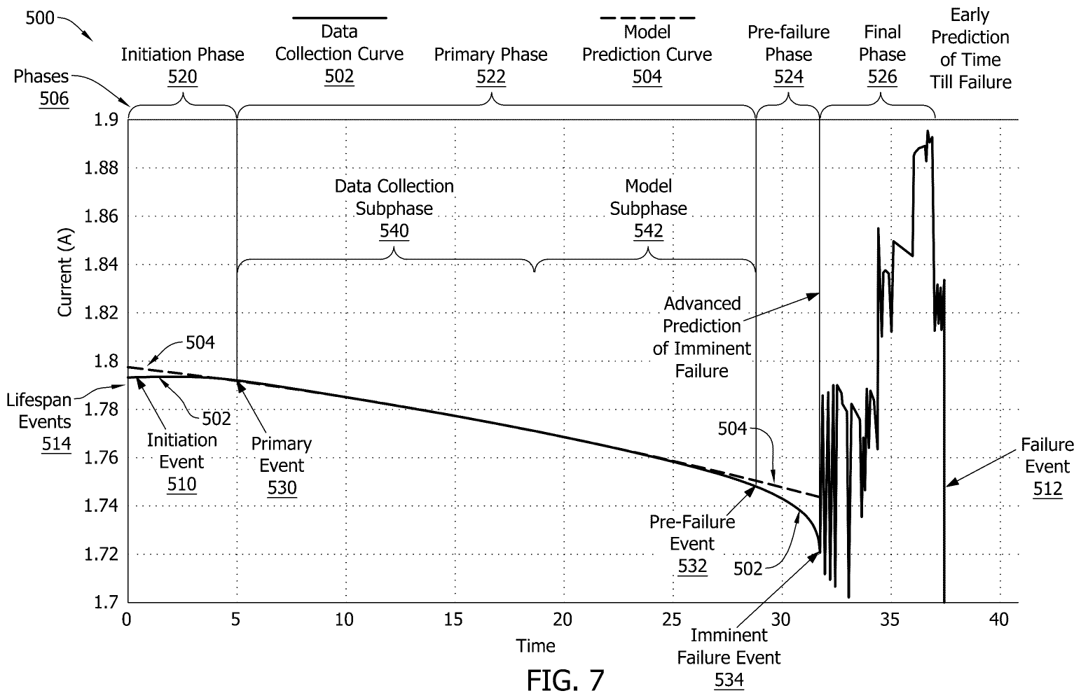

FIG. 7 is an example lifespan graph 500 displaying a current (in units of ampere) vs. lifespan (in time, e.g., days, weeks, months, or years) for an electronic device, e.g., the electronic device 410. The lifespan graph 500 includes a data collection curve 502 and an exemplary model prediction curve 504 (also referred to herein as the model 504). In embodiments described herein, a computer device, such as computer device 420 and/or the module 430, determines a plurality of phases 506, between a start time 510 (e.g., when the runtime of the electronic device 410 is zero and referred to herein as initiation event 510) and a failure time 512 (referred to herein as failure event) of the electronic device 410. Each of the phases 506 includes a beginning occurring at a first runtime and an end occurring at a subsequent second runtime. In some embodiments, the end of a phase 506 is also a beginning of a subsequent or consecutive phase. In embodiments described herein, the beginning and/or end of a phase 506 may be referred to herein as a lifespan event 514.

In the embodiments described herein, the phases 506 and/or the lifespan events 514 may be determined by the computer device based on, at least in part, a detected parameter of the electronic device 410, such as a current or a voltage detected by the sensor 434. In the exemplary embodiments described herein, the computer device may determine the phases 506 and/or the lifespan events 514, during or near the time of occurrence of the lifespan event 514, e.g., referred to generally as detection of the lifespan event 514. Additionally, and/or alternatively, the computer device may determine the phases 506 and/or the lifespan events 514, prior to the occurrence of the lifespan event 514, e.g., referred to generally as a prediction of the lifespan event 514. In the exemplary embodiments described herein, four different phases 506, delineated by five different events 514, may be determined by the computer device. In alternative embodiments, the computer device may determine any number of phases 506 and/or lifespan events 514 enabling systems and methods to function as described herein.

In embodiments described herein, the phases 506 include an initiation phase 520, a primary phase 522, a pre-failure phase 524, and a final phase 526. In exemplary embodiments described herein, there are three lifespan events 514 between the initiation event 510 and the failure event 512. The lifespan events 514 include a primary event 530 between the initiation phase 520 and the primary phase 522, a pre-failure event 532 between the primary phase 522 and the pre-failure phase 524, and an imminent failure event 534, between the pre-failure phase 524 and the final phase 526. The initiation phase 520 spans from the initiation event 510 to the primary event 530. The primary phase 522 spans from the primary event 530 to the pre-failure event 532. The pre-failure phase 524 spans from pre-failure event 532 to the imminent failure event 534. The final phase 526 spans from the imminent failure event 534 to the failure event 512. In embodiments described herein, one or more of these phases 506 may be divided into two or more subphases. In the exemplary embodiment described herein, the primary phase 522 is divided into two subphases including a data collection subphase 540 and a model subphase 542.

The initiation phase 520 occurs between the initiation event 510 and the subsequent primary event 530 delineating the initiation phase 520 from the subsequent primary phase 522. The computer device may determine the initiation event 510 by determining when the sensor 434 detects a current, for the first time, in the electronic device 410. In some embodiments, the computer device may determine the initiation event 510 by determining when the power source 432 first supplies power to the electronic device 410. In some alternative embodiments, the computer device may determine the initiation event 510 by determining when the sensor 434 detects a voltage, for the first time, in the electronic device 410. In some embodiments, the computer device may detect a voltage or a current to confirm that the power source 432 (or the electronic device 410) is operational. In some embodiments, during the initiation phase 520, the detected current may be substantially constant.

In some embodiments, the computer device may determine the primary event 530 by determining when the detected current is changed from the substantially constant current during the initiation phase 520. For example, in some embodiments, the computer device may determine a slope of the detected current and the computer device may compare this slope to a slope criterion. The computer device may determine that the primary event 530 occurs when the computer device determines that the criterion is satisfied. In some alternative embodiments, the computer device may determine that the primary event 530 occurs a threshold time after the initiation event 510. In some embodiments, the computer device may determine the primary event 530 occurs a period of time, e.g., days or weeks, after the initiation event 510. In some embodiments, the computer device may determine the primary event 530 occurs a percentage of the expected lifespan, as provided by the manufacturer of the electronic device 410. The initiation event 510 may occur at a time when the percentage of the expected lifespan is between 5-10%, between 2-5%, or between 2-15%. In some embodiments, the computer device may determine the primary event 530 occurs a percentage of a constantly applied voltage level or setpoint, as provided by the manufacturer of the electronic device 410.

As mentioned above, in the exemplary embodiment, the primary phase 522 is divided into two subphases including the data collection subphase 540 and the model subphase 542. During the data collection subphase 540, the computer device collects and/or saves an input data set of the parameter detected by the sensor 434. In the illustrated embodiment, the input data set includes detected current over the data collection subphase 540. The computer device utilizes the input data to generate the model 504. In some embodiments, the computer device generates the model 504 by fitting a polynomial equation that models and is enabled to predict future values from the input data. In some alternative embodiments, the computing device applies the input data set to a trained lifespan model to generate the model 504. In alternative embodiments, the computer device may utilize any suitable methodology to generate the model 504 using the input data collected during the data collection subphase 540. In embodiments described herein, the computer device determines the delineation between the data collection subphase 540 and the model subphase 542 using any suitable methodology, for example the computer device may determine the end of the data collection subphase 540 based on a threshold time from the primary event 530 and/or the initiation event 510. In some embodiments, the computer device may determine that the end of the data collection subphase 540 occurs during a period of time, e.g., days, weeks, or months, after initiation event 510. In some embodiments, the computer device may determine that the end of the data collection subphase 540 by determining a percentage of the expected lifespan, as provided by the manufacturer of the electronic device 410. The percentage of the expected lifespan for the end of data collection subphase 540 may be between 30%-40% of the expected lifespan, between 20%-30% of the expected lifespan, or between 25%-45% of the expected lifespan.

In some embodiments, the computer device collects and or saves input data during any suitable phase 506, including the data collection subphase 540 and or during the model subphase 542. For example, the computer device may collect input data during the model subphase 542 to generate an updated model in real time.

In some embodiments, the computer device may detect the pre-failure event 532 when the computer device determines that the detected parameter, e.g., detected current, is changed from the model 504. In some embodiments, the computer device may determine that the pre-failure event 532 occurs when the computer device determines that the rate of change of the detected current satisfies a detection criterion. In some embodiments, the computer device may determine that the pre-failure event 532 occurs when the computer device determines that the detected current is different than the model 504 by a detection criterion. In some embodiments, the detection criterion may include a percent error difference between a 0.1% and 0.5% between the data collection curve 502 and the model 504, a difference between a 0.1% and 1% between the data collection curve 502 and the model 504, or difference between a 0.5% and 1.5% between the data collection curve 502 and the model 504. In some embodiments, the computer device may detect the pre-failure event 532 when the computer device determines that a slope of a detected parameter, e.g., detected current, is changed from a previous slope by the detection criterion. In some embodiments, the computer device may detect the pre-failure event 532 when the computer device determines that a slope of a detected parameter, e.g., detected current, is changed from a slope of the model 504 by the detection criterion.

In some embodiments, the computer device may detect the imminent failure event 534 when the computer device determines that a presently detected parameter, e.g., the detected current, is changed from prior value(s) of the detected parameter. In some embodiments, the computer device may determine that the imminent failure event 534 occurs when the computer device determines that the detected current is different than prior value(s) of detected current, by a detection criterion. For example, the computer device may compare the presently detected current to any prior values of detected current including a current detected immediately prior to the presently detected current or the detected current during any of the prior phases such as during the model subphase 542 and/or the pre-failure phase 524. In some embodiments the detected criterion may include, for example and without limitation, a threshold changes in the value between the presently detected current and a prior current value, a threshold change in slope of the current between a previous slope and a present slope, or a threshold change in a rate of change of the slope of the current between a previously detected value and a presently detected value. In some embodiments the detected criterion may include, for example and without limitation, a threshold percent change between 1.5%-3%, between 1%-3.5%, or between 2%-4%. For example, the computer device may detect that the imminent failure event 534 occurs when the current is changed by 4% of an immediately prior detected current. The threshold percent change may be determined based on empirical data. For example, empirical data show that when the current reduces by a first threshold percent change such as 1%-3%, an imminent failure event occurs, and that when the current reduces by a second threshold percent change such as 3%-5%, a failure event occurs.

In embodiments described herein, the computer device detects the failure event 512 by determining when the electronic device 410 is no longer capable of holding or drawing any current. The failure event 512 is associated with any failure event that causes a component of the electronic device 410, such as the filament, to no longer be able to transmit a current and/or a supplied voltage, such as when the filament breaks. In some alternative embodiments, additional or alternative failure modes may be detected by the computer device.

As mentioned above, the computer device may determine, e.g., detects or predicts, the lifespan events 514. As described above, the computer device detects the lifespan events 514, based on, at least one of the detected parameter, the model 504, and/or a detection criterion, during, or at the time of, occurrence of the lifespan event 514. In some embodiments, the computer device predicts an estimate of a time till failure event 512 based on, at least in part, the detected lifespan event 514.

In the exemplary embodiments, the computer device is also enabled to predict the time till occurrence of the lifespan events 514, well in advance of the event 514 actually occurring, based on, at least one of the detected parameter, the model 504, and/or a prediction criterion. In some embodiments, the computer device predicts an estimate of a time till failure event 512 based on, at least in part, the predicted time till occurrence of the lifespan event 514. In some embodiments, the computer device may predict multiple different estimates of the time till failure during any of the phases 506. For example, the computer device may predict a first estimate (referred to herein as in advanced estimate) of a time till failure during the primary phase 522. In another example, the computer device may predict a second estimate (referred to herein as in imminent estimate) of a time till failure during the pre-failure phase 524.

In some embodiments, the computer device predicts a time till the pre-failure event 532 will occur. In some embodiments, the computer device predicts the pre-failure event 532 at a time when the model 504 predicts that the current will satisfy a prediction criterion. The prediction criterion may include the computer device determining that the current will be reduced by a threshold percentage as compared to an earlier current value, e.g., the current value at, or near, the primary event 530 or the initiation event 510. The threshold percentage may be between 2-3%, between 2-4%, between 1-5%, or between 3-6%. In embodiments described herein, the computer device may utilize the predicted time till the pre-failure event 532 to predict an estimate of a time till the failure event 512. In embodiments described herein, the computer device may predict the time till the pre-failure event 532, and/or the estimate of time till failure event 512, prior to the pre-failure event 532 occurring, for example during the primary phase 522. The computer device may estimate the time till the failure event 512 by adding a period of time to the predicted time till the pre-failure event 532. In some embodiments, the computer device may estimate the time till the failure event 512 using the predicted time till the pre-failure event 532 and a percentage of an initial current value, e.g., the current value at, or near, the primary event 530 or the initiation event 510. In embodiments described herein, the system computer device uses the model 504 to predict a time till the pre-failure event 532, well in advance of the pre-failure event 532 actually occurring. For example, the system computer device may predict the pre-failure event 532 during the primary phase 522, e.g., during the data collection subphase 540 or during the model subphase 542. In some embodiments, the system computer device may predict the pre-failure event 532 at the end of the data collection subphase 540.

In some embodiments, the computer device predicts a time till the imminent failure event 534 will occur. In embodiments described herein, the computer device may utilize the predicted time till the imminent failure event 534 to predict an estimate of a time till the failure event 512. In embodiments described herein, the computer device may predict the time till the imminent failure event 534, and/or the estimate of time till failure event 512, prior to the imminent failure event 534 occurring, for example during the primary phase 522 and or the pre-failure phase 524. The computer device may estimate the time till the failure event 512 by adding a period of time to the predicted time till the imminent failure event 534. The computer device may estimate the time till the imminent failure event 534 occurs by determining when the model 504 satisfies a prediction criterion. In some embodiments the prediction criterion includes when the computer device determines that the model 504 predicts a decrease in the parameter as compared to a prior parameter value. For example, the prediction criterion may include the computer device determining that the model 504 predicts a reduction in the current by a threshold amount as compared to a previously detected current, for example a previously detected current at or near the primary event 530. In some embodiments, the prediction criterion includes the model 504 predicting that the current will be reduced from the current at, or near, the primary event 530, by between 5%-6%, between 4%-6%, or between 3%-7%.

In some alternative embodiments, the computer device utilizes a training data set to build a lifespan model for predicting a time till failure. For example, the lifespan model may be trained using a training data set including parameters detected by the sensor 434 for a plurality of electronic devices 410 collected over the entire lifespan of the electronic devices 410. Alternatively, the lifespan model may be trained using a training data set including parameters detected by the sensor 434 for a plurality of different electronic devices 410 collected over one or more of the phases 506. The trained lifespan model may be configured to accept one or more model inputs to generate one or more model outputs. In some embodiments, model inputs may include input data, described above, and/or additional or alternative data such as data associated with the electronic device 410 (e.g., manufacturing data such as design voltage and/or predicted lifespan curve), power supplied, factors of safety, desired or specified luminosity, etc. In some embodiments, model outputs may include, for example, a prediction of a time till failure, e.g., advanced prediction of time till failure and/or imminent prediction of a time till failure. In some embodiments, model outputs may include a prediction of time till a lifespan event 514 occurs. In some embodiments, the lifespan model may be re-training using an updated training data set including newly detected parameters/data detected by the sensor 434.

In some embodiments, the computer device may continuously monitor the current during any of the phases 506 of the lifespan to detect a change in current that may indicated a failure event will occur. For example, in some rare cases the electronic device 410 may fail very early, e.g., during the primary phase 522.

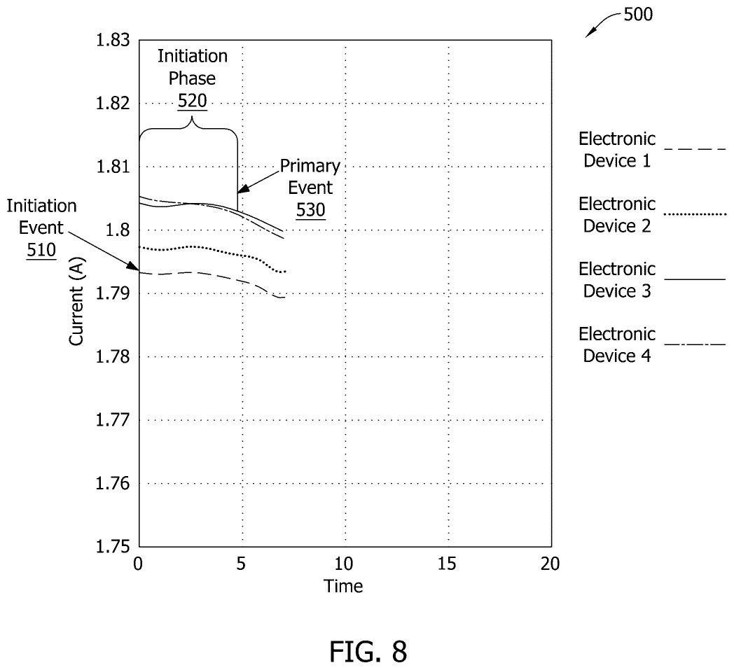

FIG. 8 is another example lifespan graph 500 displaying a current (in units of ampere) vs. lifespan (in time, e.g., days, weeks, months, or years) for a plurality of electronic devices 410, showing the initiation phase 520.

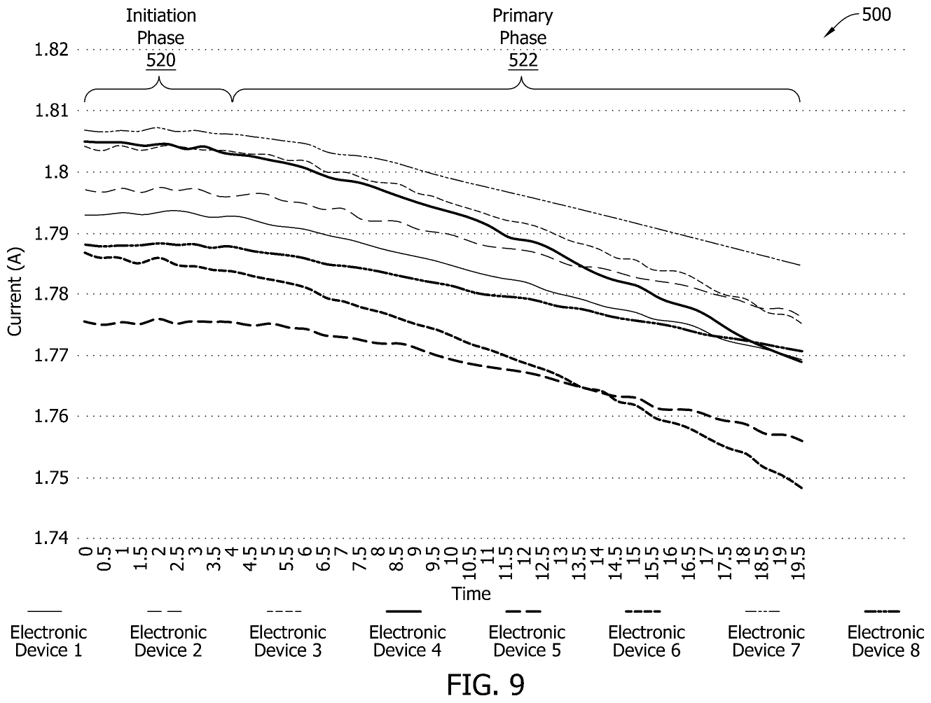

FIG. 9 is another example lifespan graph 500 displaying a current (in units of ampere) vs. lifespan (in time, e.g., days, weeks, months, or years) for a plurality of electronic devices 410, showing the initiation phase 520 and the primary phase 522.

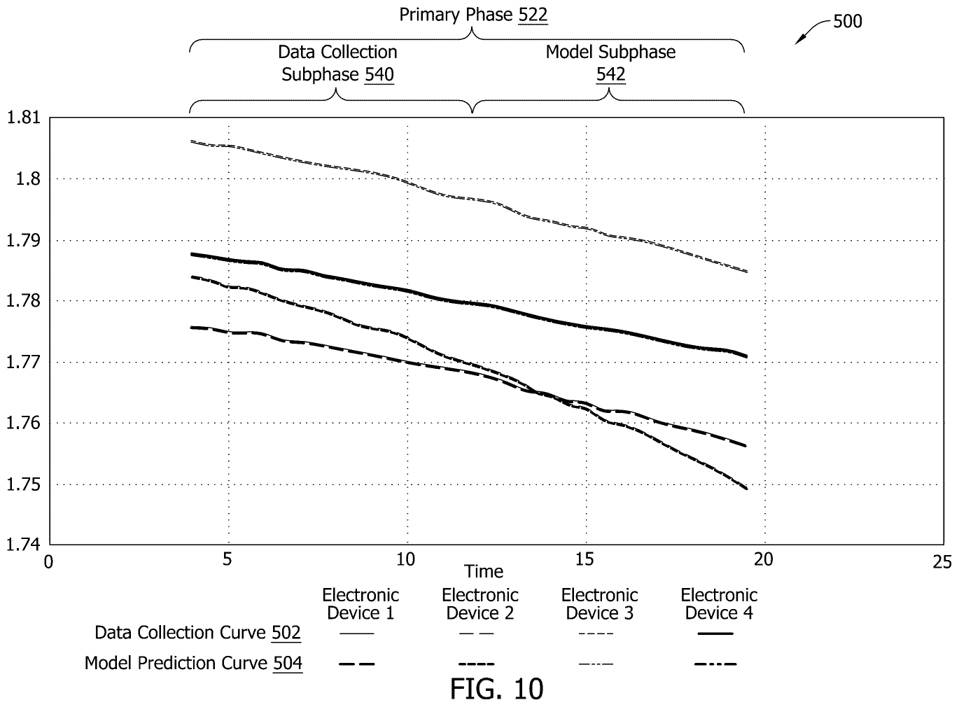

FIG. 10 is another example lifespan graph 500 displaying a current (in units of ampere) vs. lifespan (in time, e.g., days, weeks, months, or years) for a plurality of electronic devices 410, showing the primary phase 522 including the data collection subphase 540 and the model subphase 542 for both the data collection curve 502 and a model prediction curve 504.

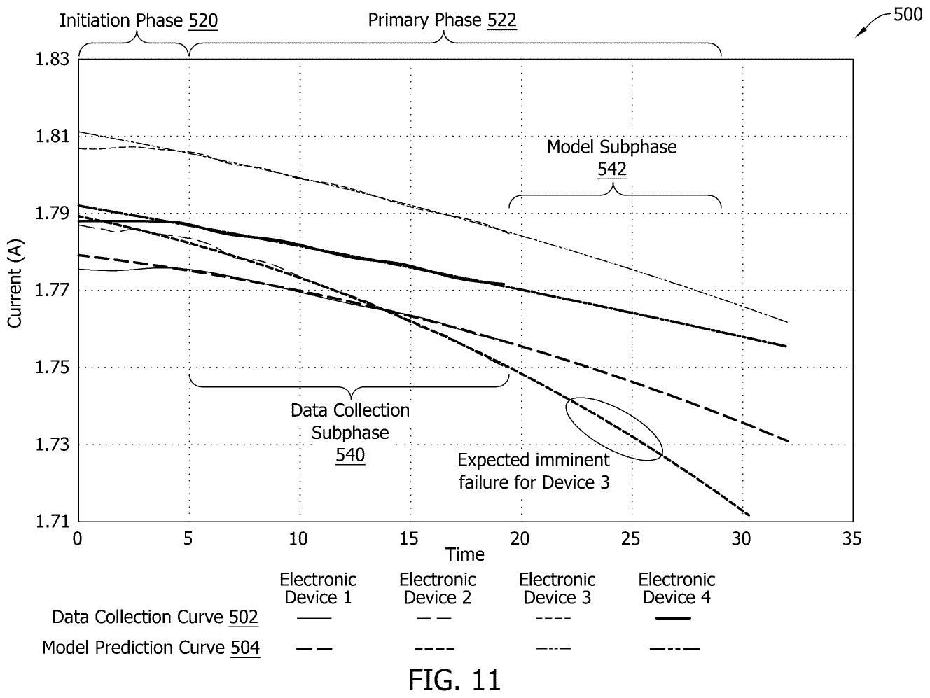

FIG. 11 is another example lifespan graph 500 displaying a current (in units of ampere) vs. lifespan (in time, e.g., days, weeks, months, or years) for a plurality of electronic devices 410, showing the initiation phase 520 and the primary phase 522 including the data collection subphase 540 and the model subphase 542 for both the data collection curve 502 and a model prediction curve 504.

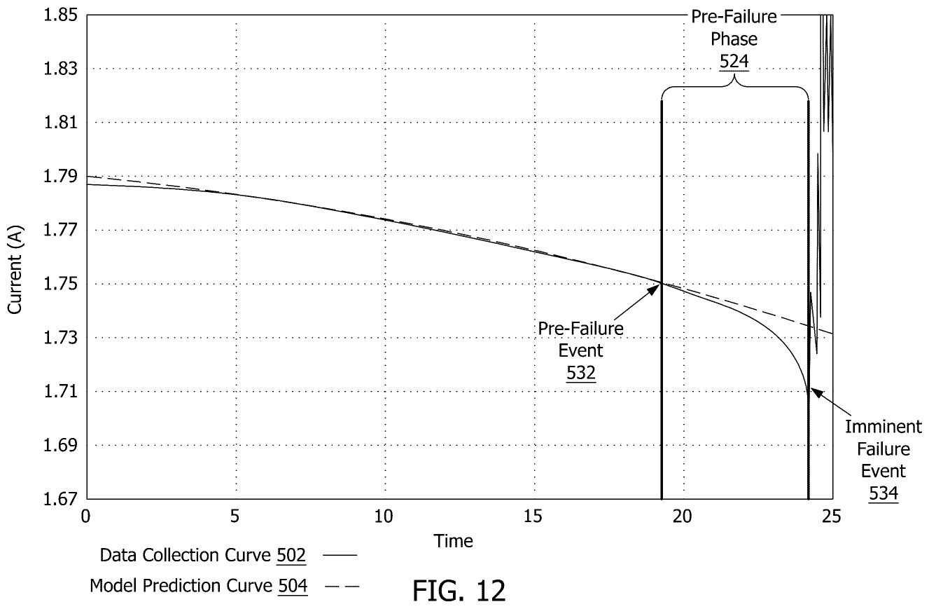

FIG. 12 is another example lifespan graph 500 displaying a current (in units of ampere) vs. lifespan (in time, e.g., days, weeks, months, or years) for an electronic device 410 showing the pre-failure phase 524.

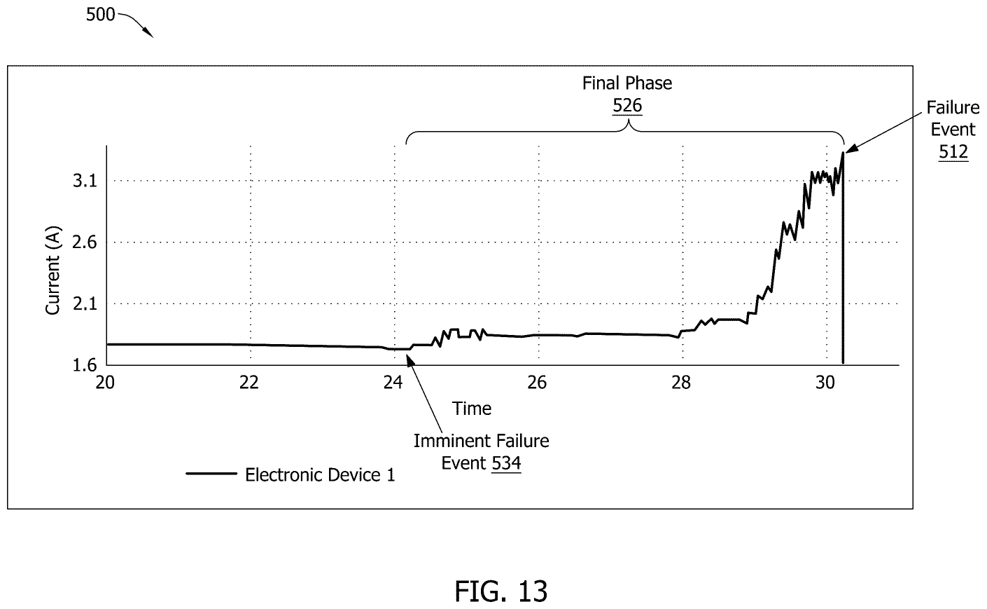

FIG. 13 is another example lifespan graph 500 displaying a current (in units of ampere) vs. lifespan (in time, e.g., days, weeks, months, or years) for an example electronic device 410 showing the final phase 526.

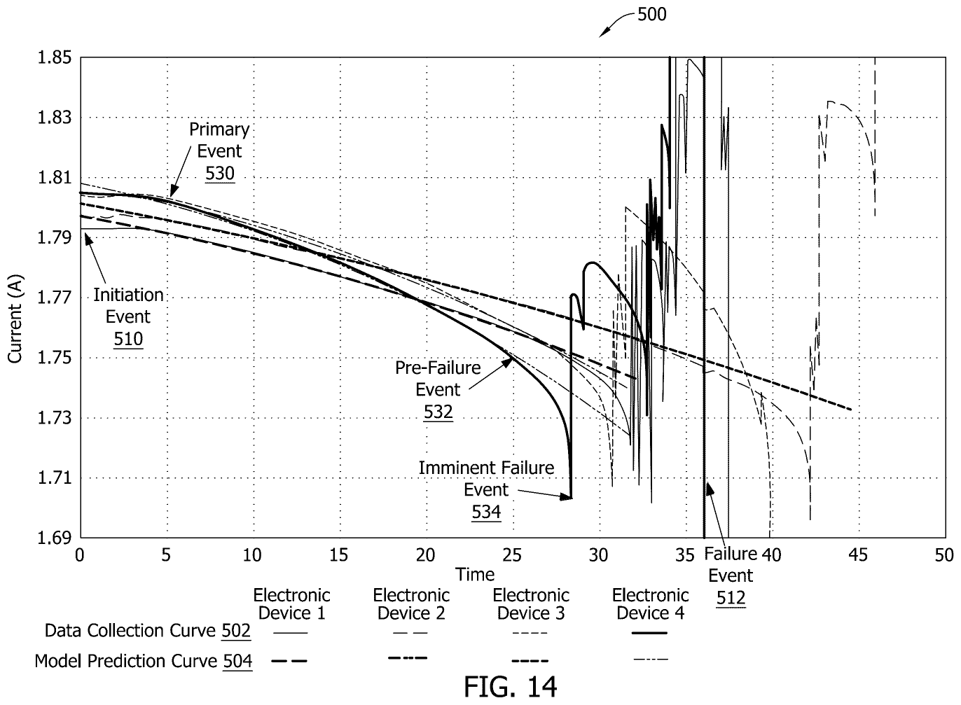

FIG. 14 is another example lifespan graph 500 displaying a current (in units of ampere) vs. lifespan (in time, e.g., days, weeks, months, or years) for a plurality of electronic devices 410 showing the phases 506 and lifespan events 514 for the data collection curve 502 and the model prediction curve 504.

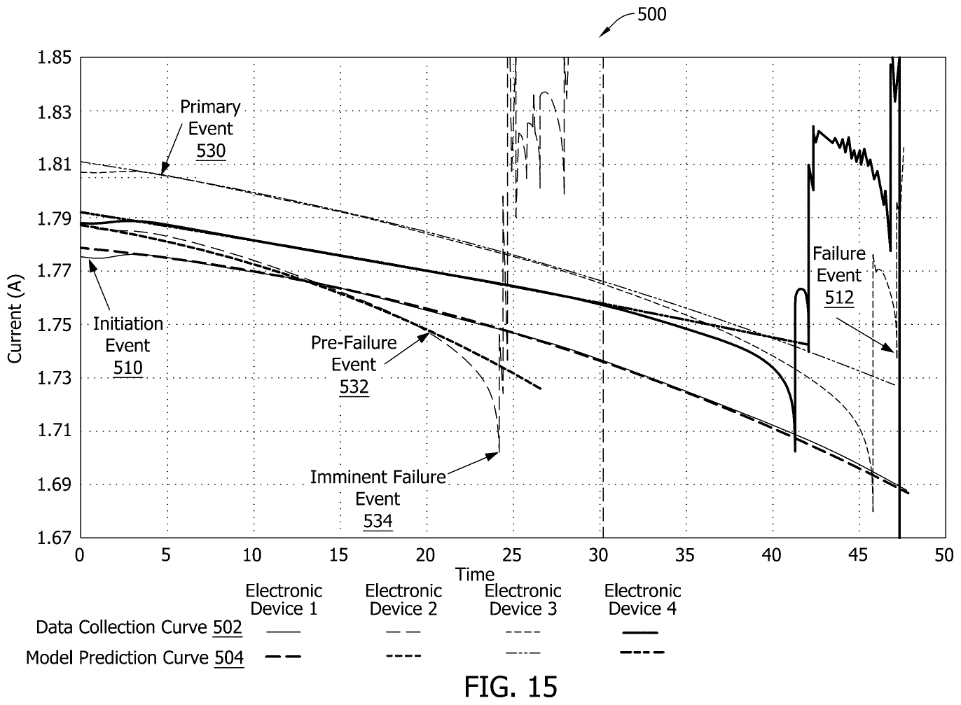

FIG. 15 is another example lifespan graph 500 displaying a current (in units of ampere) vs. lifespan (in time, e.g., days, weeks, months, or years) for a plurality of electronic devices 410 showing the phases 506 and lifespan events 514 for the data collection curve 502 and the model prediction curve 504.

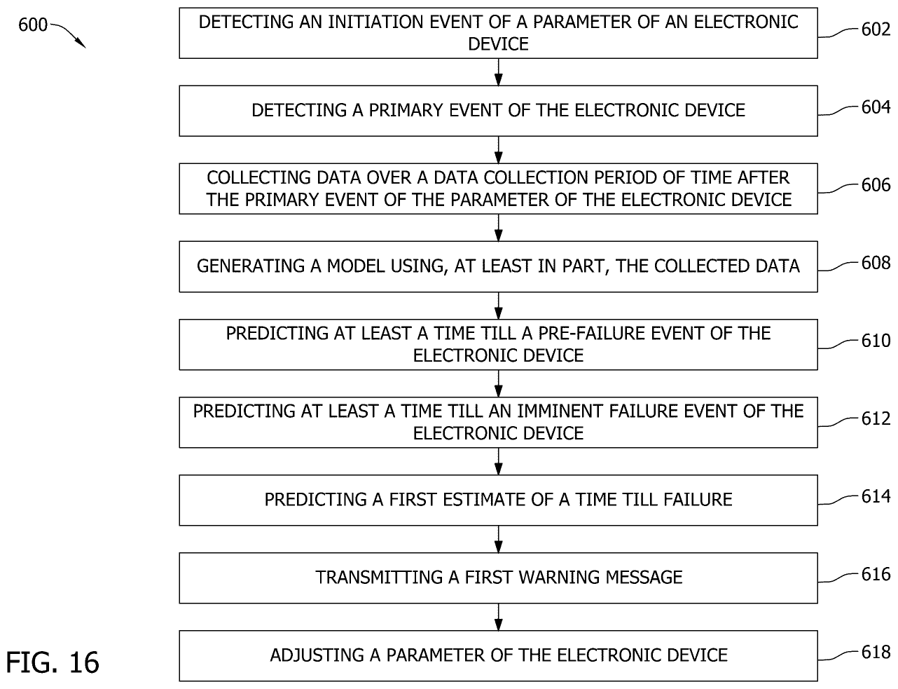

FIG. 16 is a method flow diagram for an exemplary method 600 for operating (e.g., predicting and/or detecting phases 506 and lifespan events 514, or controlling a parameter) of an electronic device 410 for use with the system shown in FIG. 4. One or more of the method steps of method 600 may be performed or executed by any suitable computer device, such as computer device 420 and/or module 430. Any parts of methods 600 and 700 may be performed in any order, unless stated otherwise, and any parts of method 600 may be performed in combination with any parts of method 700.

Method 600 may include the computer device detecting 602 the initiation event 510 of the electronic device 410. Detecting 602 the initiation event 510 may include the computer device determining that the electronic device 410 is turned on, e.g., using the detected parameter/data received from the sensor 434. For example, detecting 602 may include the computer device detecting or receiving an initially detected current or voltage from the sensor 434. In some embodiments, the method 600 includes the computer device turning on the electronic device 410. Turning on may include the computer device transmitting one or more signals to the power source 432 causing the power source 432 to supply power, for the first time, to the electronic device 410. In some embodiments, method 600 includes resetting data, clearing data caches, etc., before causing the power source 432 to supply power, for the first time, to the electronic device 410.

The method 600 includes the computer device detecting 604 the primary event 530. Detecting 604 the primary event 530 may include the computer device determining that a detected parameter of the electronic device 410 has stabilized, for example, the computer device may detect that detected parameter is holding a substantially constant value, e.g., a substantially constant current. In some embodiments, detecting 604 the primary event 530 may include the computer device determining that the primary event 530 occurs at a percentage of the expected lifespan, as provided by the manufacturer of the electronic device 410. In some embodiments, the computer device may determine the primary event 530 occurs a percentage of a constantly applied voltage level or setpoint, as provided by the manufacturer of the electronic device 410. In some embodiments, detecting 604 the primary event 530 may include the computer device determining that the primary event 530 occurs as at a time that is a percentage of the expected lifespan, e.g., as provided by a manufacturer. In some embodiments, detecting 604 the primary event 530 may include the computer device determining that a time period has passed, e.g., days or weeks, after the detection of the initiation event 510.

The method 600 includes the computer device collecting 606 sensor data received from the sensor 434 during the data collection subphase 540. Collecting data may include the computer device collecting data over a period of time after the initiation event 510.

In some rare cases, the electronic device 410 may fail early, e.g., an early failure event during the primary phase 522, which may be detected by a rapid change, or rate of change, of current, similar to detection of the pre-failure event 532 or detection of the imminent failure event 534. The method 600 may include the computer device detecting changes or rate of changes in the current at any time during the lifespan, to detect an early failure event.

The method 600 includes the computer device generating 608 the model 504 using the collected data. Generating 608 the model 504 may include the computer device fitting a polynomial equation to the collected data. In some embodiments, generating 608 the model 504 may include the computer device training or tuning the lifespan model using collected data for a plurality of electronic devices 410, over the data collection period of time and/or over the entire lifespan of the plurality of electronic devices 410 and then applying input data, e.g., the collected data, such that the lifespan model generates the model 504 as an output.

The method 600 includes computer device predicting 610 at least a time till the pre-failure event 532 will occur (e.g., predicting a time of an event of the electronic device 410 that occurs before, or at, the pre-failure event 532). In some embodiments, predicting 610 include the computer device determining the pre-failure event 532 at a time when the model 504 predicts that the current will satisfy a prediction criterion. In some embodiments, the prediction criterion may include the computer device determining that the current will be reduced by a threshold percentage as compared to an earlier current value, e.g., the current value at, or near, the primary event 530 or the initiation event 510. For example, in some embodiments, the threshold percentage may be between 0.5-3%, between 1-2%, between 0.5-3.5%, or between 1-3%.

The method 600 includes the computer device predicting 612 at least a time till the imminent failure event 534 (e.g., predicting a time of an event of the electronic device 410 that occurs before, or at, the imminent failure event 534). In some embodiments, the method 600 includes the computer device predicting a time till the imminent failure event 534. Predicting 612 may include the computing device utilizing the model 504 to predict the time till the imminent failure event 534. Predicting 612 may include the computer device determining when the model 504 satisfies a prediction criterion. In some embodiments, the prediction criterion includes when the computer device determines that the model 504 predicts the parameter will decrease as compared to a prior parameter value. For example, in some embodiments, the computer device may predict 612 that the imminent failure event 534 occurs when the computer device determines that the detected current is different than prior value(s) of detected current, by a detection criterion. For example, the computer device may compare the presently detected current to any prior values of detected current including a current detected immediately prior to the presently detected current or the detected current during any of the prior phases such as during the model subphase 542 and/or the pre-failure phase 524. In some embodiments the detected criterion may include, for example and without limitation, a threshold change in the value between the presently detected current and a prior current value, a threshold change in slope, or a threshold change in a rate of change of the slope. In some embodiments the detected criterion may include, for example and without limitation, the detection criterion is a threshold percent change between 1.5%-3%, between 1%-3.5%, or between 2%-4%. In some embodiments, the prediction criterion includes the computer predicting device using the model 504 to predict that the current will be reduced from a previous current at, or near, the primary event 530, by between 1%-2%, between 1%-3%, or between 2%-5%.

In some embodiments, the method 600 includes the computer device predicting 614 a first estimate of a time till failure event 512. Predicting 614 may include the computer device estimating the time till the failure event 512 by adding a period of time to the predicted time till the imminent failure event 534 or the predicted time till the pre-failure event 532. In embodiments described herein, the computer device may predict the time till the imminent failure event 534, and/or the estimate of time till failure event 512, prior to the imminent failure event 534 occurring, for example during the primary phase 522 and or the pre-failure phase 524. In embodiments described herein, the computer device may predict the time till the pre-failure event 532, and/or the estimate of time till failure event 512, prior to the pre-failure event 532 occurring, for example during the primary phase 522.

The method 600 includes the computer device transmitting 616 one or more warning messages indicating the first estimate of the time till failure event 512. Transmitting 616 may include the computer device transmitting one or more signals to the user interface 426 causing the user interface 426 to display the warning message. Transmitting 616 warning messages may occur after any of the following: predicting 610 the pre-failure event 532, predicting 612 at least a time till imminent failure event 534, and/or after predicting 614 a first estimate of time till failure event 512. Warning messages may indicate a predicted time till any of the pre-failure event 532, the imminent failure event 534, and/or the failure event 512.

In some embodiments, the method 600 includes the computer device adjusting 618 a parameter of the electronic device 410. Adjusting 618 may include the computer device transmitting one or more signals to the power source 432 to adjust, e.g., increase or decrease, the amount of power supplied to the electronic device 410. In some embodiments, adjusting 618 includes the computer device transmitting one or more signals to the power source 432 to decrease the amount of power supplied to the electronic device 410. In some embodiments, the computer device adjusting 618 a parameter of the electronic device is automatically triggered by a predicted or detected event, or by comparing a predicted or detected event to a trigger criterion. For example, a trigger criterion may include the computer device comparing the predicted time till failure to a threshold amount of time. In some embodiments, the method 600 includes the computer device reducing the power delivered to the electronic device 410 from the initiation phase 510 in order to extend the lifespan of the electronic device 410. In some embodiments, the computer device causes the power source 432 to supply between 90-99%, between 80-99%, or between 85-95% of the rated power. In some embodiments, the computer device causes the power source 432 to supply between 45-55%, between 40-50%, or between 50-60% of the rated power.

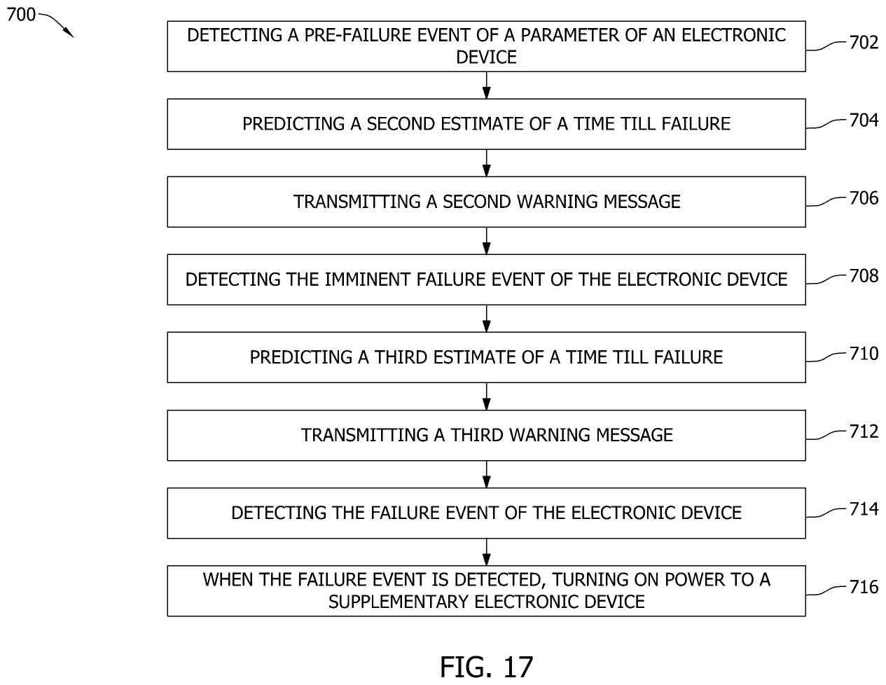

FIG. 17 is a method flow diagram for another exemplary method 700 operating (e.g., predicting and/or detecting phases 506 and lifespan events 514, or controlling a parameter) of an electronic device 410 for use with the system shown in FIG. 6. One or more of the method steps of method 700 may be performed or executed by any suitable computer device, such as computer device 420 and/or module 430.

The method 700 includes the computer device detecting 702 the pre-failure event 532. Detecting 702 may include the computer device determining that the detected parameter, e.g., detected current, is changed from the model 504. In some embodiments, detecting 702 may include the computer device determining that the detected current is different than the model 504 by a detection criterion. The detection criterion may include a percent error difference between a 2% and 5% between the data collection curve 502 and the model 504, a difference between a 1% and 4% between the data collection curve 502 and the model 504, or difference between a 2 and 3% difference between the data collection curve 502 and the model 504.

The method 700 includes the computer device predicting 704 a second estimate of a time till failure. Predicting 704 may include the computer device estimating the time till the failure event 512 by adding a period of time to the detected pre-failure event 532.

The method 700 includes the computer device transmitting 706 a second warning message indicating the second estimate of the time till failure and/or the detected pre-failure event 532. Transmitting 706 may include the computer device transmitting one or more signals to the user interface 426 causing the user interface 426 to display the second warning message.

The method 700 includes the computer device detecting 708 the imminent failure event 534. In some embodiments, detecting 708 includes the computer device determining that a presently detected parameter, e.g., the detected current, is changed from prior value(s) of the detected parameter. In some embodiments, the computer device may detect that the imminent failure event 534 occurs when the computer device determines that the detected current is different than prior value(s) of detected current, by a detection criterion. For example, the computer device may compare a presently detected current to any prior values of detected current including a current detected immediately prior to the presently detected current or the detected current during any of the prior phases such as during the model subphase 542 and/or the pre-failure phase 524. In some embodiments the detected criterion may include, for example and without limitation, a threshold changes in the value between the presently detected current and a prior current value, a threshold change in slope, or a threshold change in a rate of change of the slope.

The method 700 includes the computer device predicting 710 a third estimate of a time till failure. Predicting 710 may include the computer device estimating the time till the failure event 512 by adding a period of time to the detected imminent failure event 534.

The method 700 may include the computer device includes the computer device transmitting 712 a third warning message indicating the third estimate of the time till failure and/or the detected imminent failure event 534. Transmitting 712 may include the computer device transmitting one or more signals to the user interface 426 causing the user interface 426 to display the third warning message.

The method 700 may include the computer device detecting 714 the failure event 512. Detecting may include the computer device determining when the electronic device 410 is no longer capable of transmitting a current and/or a voltage. For example, the computer device may compare the current, if any, to a minimum threshold value of current. The computer device detects the failure event 512, when the computer device determines that the detected current is less than the minimum threshold.

In some alternative embodiments, the method 700 may include the computer device turning on 716 the supplementary electronic device 440, after detecting the failure event 512 or after predicting 716 the third estimate of a time till failure. Turning on 716 the supplementary electronic device 440 may include the computer device transmitting one or more signals to the power source 432 causing the power source 432 to supply power to the supplementary electronic device 440.

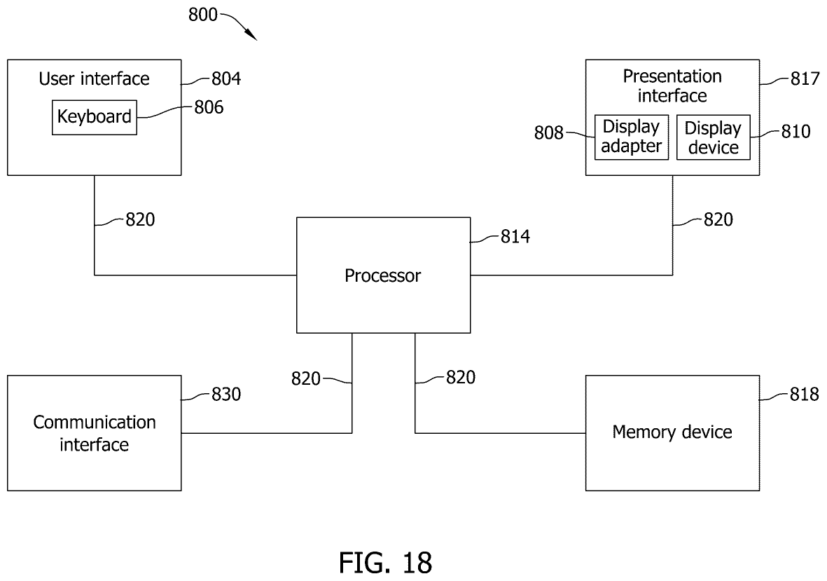

At least parts of methods described herein may be implemented in any suitable computer device 800 and software implemented therein. FIG. 18 is a block diagram of an example computer device 800. In the example embodiment, computer device 800 includes a user interface 804 that receives at least one input from a user. User interface 804 may include a keyboard 806 that enables the user to input pertinent information. User interface 804 may also include, for example, a pointing device, a mouse, a stylus, a touch sensitive panel (e.g., a touch pad and a touch screen), a gyroscope, an accelerometer, a position detector, and/or an audio input interface (e.g., including a microphone).

Moreover, in the example embodiment, computer device 800 includes a presentation interface 817 that presents information, such as detected or predicted events and/or sensed parameters, such as current, to the user. Presentation interface 817 may also include a display adapter 808 that is coupled to at least one display device 810. More specifically, in the example embodiment, display device 810 may be a visual display device, such as a cathode ray tube (CRT), a liquid crystal display (LCD), a light-emitting diode (LED) display, and/or an “electronic ink” display. Alternatively, presentation interface 817 may include an audio output device (e.g., an audio adapter and/or a speaker) and/or a printer.

Computer device 800 also includes a processor 814 and a memory device 818. Processor 814 is coupled to user interface 804, presentation interface 817, and memory device 818 via a system bus 820. In the example embodiment, processor 814 communicates with the user, such as by prompting the user via presentation interface 817 and/or by receiving user inputs via user interface 804. The term “processor” refers generally to any programmable system including systems and microcontrollers, reduced instruction set computers (RISC), complex instruction set computers (CISC), application specific integrated circuits (ASIC), programmable logic circuits (PLC), and any other circuit or processor capable of executing the functions described herein. The above examples are for illustration purposes only, and thus are not intended to limit in any way the definition and/or meaning of the term “processor.”

In the example embodiment, memory device 818 includes one or more devices that enable information, such as executable instructions and/or other data, to be stored and retrieved. Moreover, memory device 818 includes one or more computer readable media, such as, without limitation, dynamic random-access memory (DRAM), static random-access memory (SRAM), a solid-state disk, and/or a hard disk. In the example embodiment, memory device 818 stores, without limitation, application source code, application object code, configuration data, additional input events, application states, assertion statements, validation results, and/or any other type of data. Computer device 800, in the example embodiment, may also include a communication interface 830 that is coupled to processor 814 via system bus 820. Moreover, communication interface 830 is communicatively coupled to data acquisition devices.

In the example embodiment, processor 814 may be programmed by encoding an operation using one or more executable instructions and providing the executable instructions in memory device 818. In the example embodiment, processor 814 is programmed to select a plurality of measurements that are received from data acquisition devices.

In operation, a computer executes computer-executable instructions embodied in one or more computer-executable components stored on one or more computer-readable media to implement aspects of the invention described and/or illustrated herein. The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

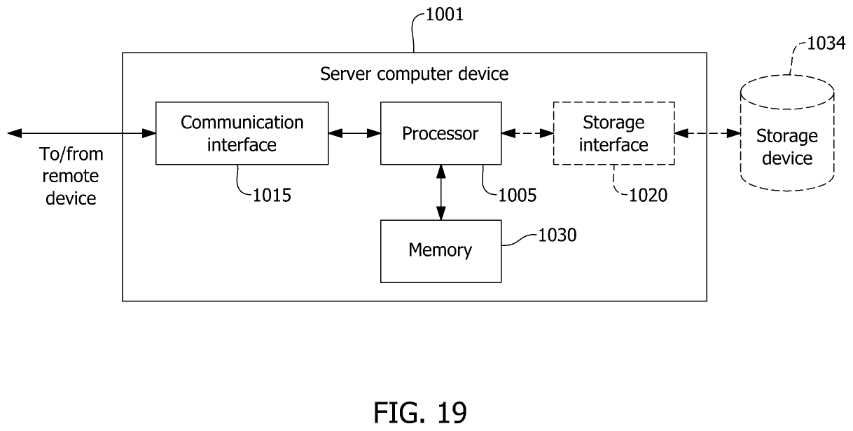

At least parts of methods 600 and/or 700 described herein may also be implemented with a server computer device 1001. FIG. 19 illustrates an example configuration of a server computer device 1001. Server computer device 1001 also includes a processor 1005 for executing instructions. Instructions may be stored in a memory area 1030, for example. Processor 1005 may include one or more processing units (e.g., in a multi-core configuration).

Processor 1005 is operatively coupled to a communication interface 1015 such that server computer device 1001 is capable of communicating with a remote device or another server computer device 1001. For example, communication interface 1015 may receive data from system 12, via the Internet.

Processor 1005 may also be operatively coupled to a storage device 1034. Storage device 1034 is any computer-operated hardware suitable for storing and/or retrieving data. In some embodiments, storage device 1034 is integrated in server computer device 1001. For example, server computer device 1001 may include one or more hard disk drives as storage device 1034. In other embodiments, storage device 1034 is external to server computer device 1001 and may be accessed by a plurality of server computer devices 1001. For example, storage device 1034 may include multiple storage units such as hard disks and/or solid-state disks in a redundant array of independent disks (RAID) configuration. storage device 1034 may include a storage area network (SAN) and/or a network attached storage (NAS) system.

In some embodiments, processor 1005 is operatively coupled to storage device 1034 via a storage interface 1020. Storage interface 1020 is any component capable of providing processor 1005 with access to storage device 1034. Storage interface 1020 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 1005 with access to storage device 1034.

At least one technical effect of the systems and methods described herein includes (a) advanced prediction of a time till failure of an electronic device; (b) imminent prediction of a time till failure of an electronic device; (c) advanced detection and prediction of a time till failure of an electronic device; and (d) accurate prediction of a time till failure of an electronic device.

Example embodiments of systems and methods of lamp failure are described above in detail. The systems and methods are not limited to the specific embodiments described herein but, rather, components of the systems and/or operations of the methods may be utilized independently and separately from other components and/or operations described herein. Further, the described components and/or operations may also be defined in, or used in combination with, other systems, methods, and/or devices, and are not limited to practice with only the systems described herein.

As used herein, an element or step recited in the singular and proceeded with the word “a” or “an” should be understood as not excluding plural elements or steps, unless such exclusion is explicitly recited. Furthermore, references to “example” or “one example” of the present disclosure are not intended to be interpreted as excluding the existence of additional examples that also incorporate the recited features. Further, to the extent that terms “includes,” “including,” “has,” “contains,” and variants thereof are used herein, such terms are intended to be inclusive in a manner similar to the term “comprises” as an open transition word without precluding any additional or other elements.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A system for operating a halogen lamp, the system comprising:
a sensor configured to detect a parameter of the lamp; and
a processor communicatively coupled to at least one memory storing instructions that when executed by the processor cause the processor to:
receive the parameter detected by the sensor over a data collection period of time;
generate a model based on, at least in part, the received parameter detected by the sensor over the data collection period of time; and
using the model, predict a time till at least a pre-failure event when a pre-failure criterion will be satisfied.

2. The system of claim 1, wherein the processor is further configured to
using the model, predict the time till the pre-failure event when a pre-failure criterion will be satisfied, wherein the processor determines that the pre-failure criterion is satisfied when the model predicts that the parameter will deviate from a previous value of the parameter by a threshold amount.

3. The system of claim 2, wherein the threshold amount is between 1% and 6%.

4. The system of claim 1, wherein the data collection period of time corresponds to a primary phase of the lamp, and during the primary phase, the parameter decreases over time.

5. The system of claim 4, wherein the processor is further configured to:
determine a start of the primary phase by:
detecting a primary event using sensor data; and
selecting a time corresponding to the primary event as the start of the primary phase.

6. The system of claim 1, wherein the processor is further configured to:
generate the model based on, at least in part, the received parameter detected by the sensor over the data collection period of time by fitting a polynomial equation to the received parameter.

7. The system of claim 1, wherein the processor is configured to predict the time till failure by adding an amount of time to the predicted pre-failure event.

8. The system of claim 7, wherein the processor is configured to predict a time till failure based on, at least in part, the predicted time till the pre-failure event.

9. The system of claim 1, wherein the processor is further configured to:
detect the pre-failure event by comparing a present value of the detected parameter to a previously detected parameter value; and
predict an updated time till failure based on, at least in part, the detected pre-failure event.

10. The system of claim 1, wherein the processor is further configured to:
detect an imminent failure event by comparing a present value of the detected parameter to a previously detected parameter value; and
predict an updated time till failure based on, at least in part, the detected imminent failure event.

11. The system of claim 10, wherein the processor is further configured to:
transmit a message to be displayed on a user interface, the message indicating at least one of predicted time till failure or a predicted time till imminent failure.

12. The system of claim 1, further comprising a voltage sensor, wherein the processor is further configured to:
control voltage across the lamp using feedback from the voltage sensor.

13. The system of claim 1, wherein the sensor is a current sensor and the detected parameter is a current of the lamp.

14. A method for predicting a time till failure of a lamp, the method comprising:
receiving a parameter detected by a sensor over a data collection period of time;
generating a model based on, at least in part, the received parameter detected by the sensor over the data collection period of time; and
using the model, predict a time till at least a pre-failure event when a pre-failure criterion will be satisfied.

15. The method of claim 14, wherein the method further includes:
using the model, predict the time till the pre-failure event when a pre-failure criterion will be satisfied, wherein the pre-failure criterion is satisfied when the model predicts that the parameter will deviate from a previous value of the parameter by a threshold amount.

16. The method of claim 15, wherein the threshold amount is between 1% and 6%.

17. The method of claim 14, wherein the data collection period of time corresponds to a primary phase of the lamp, and during the primary phase, the parameter decreases over time.

18. The method of claim 14, wherein the method further includes:
determining a start of an initiation phase using sensor data.

19. The method of claim 14, the method further including:
adjusting voltage across the lamp to a user defined level.

20. A non-transitory computer readable medium having computer-executable instructions embodied thereon for implementing operating a halogen lamp, wherein when executed by at least one processor, the computer-executable instructions cause the at least one processor to:
receive a parameter detected by a sensor over a data collection period of time;
generate a model based on, at least in part, the received parameter detected by the sensor over the data collection period of time; and
using the model, predict a time till at least a pre-failure event when a pre-failure criterion will be satisfied.
